(19) United States
(12) Patent Application Publication
(10) Pub. No.: US 2018/0068878 A1
(43) Pub. Date: Mar. 8, 2018

(54) TAPE STICKING APPARATUS AND TAPE STICKING METHOD

(71) Applicant: Panasonic Intellectual Property Management Co., Ltd., Osaka (JP)

(72) Inventors: SATOSHI ADACHI, Osaka (JP); AKIRA KAMEDA, Osaka (JP)

(21) Appl. No.: 15/691,846

(22) Filed: Aug. 31, 2017

(30) Foreign Application Priority Data
Sep. 8, 2016 (JP) 2016-175121

(51) Int. Cl. H01L 21/67; H01L 21/683

(52) U.S. Cl. CPC H01L 21/67132; H01L 21/6836

(57) ABSTRACT

Disclosed is a tape sticking apparatus in which an end region of a board formed of a film-shaped member is supported by a backup stage, a tape slice for bonding a component is pressed against the end region of the board together with a separator attached to an upper surface of the tape slice to stick the tape slice to the end region of the board, and then the separator is pulled up from the tape slice to separate the separator from the tape slice, the apparatus including a porous material portion which is provided at an upper portion of the backup stage and supports a lower surface of the end region of the board; and a suction mechanism which sucks the end region of the board through the porous material portion.

### BACKGROUND

### 1. Technical Field

The present disclosure relates to a tape sticking apparatus that sticks a tape slice for bonding components to an end region of a board formed of a film-shaped member and a tape sticking method.

### 2. Description of Related Art

In a manufacturing line of a liquid crystal panel, tape sticking work for sticking a tape slice for bonding a component to an electrode is executed before placing a component such as a drive circuit to an electrode provided in an end region of a board. A tape sticking apparatus executing the tape sticking work has a configuration in which operations of pressing the tape slice against the end region of the board to stick thereto together with a separator attached to an upper surface of the tape slice, and pulling up the separator from the tape slice to separate the separator are repeated after a lower surface of the end region of the board is supported by a backup stage (see Japanese Patent Unexamined Publication No. 2014-107524).

### SUMMARY

A tape sticking apparatus of the disclosure which supports an end region of a board formed of a film-shaped member by a backup stage, presses a tape slice for bonding a component against the end region of the board together with a separator attached to an upper surface of the tape slice to stick the tape slice to the end region of the board, and then pulls up the separator from the tape slice to separate the separator from the tape slice, the apparatus including: a porous material portion which is provided at an upper portion of the backup stage and supports a lower surface of the end region of the board; and a suction mechanism which sucks the end region of the board through the porous material portion.

According to the disclosure, it is possible to prevent a situation in which the end region of the board is pulled and lifted up and the portion is deformed or the like when pulling up the separator from the tape slice stuck to the board formed of the film-shaped member.

### BRIEF DESCRIPTION OF DRAWINGS

FIG. 1 is a perspective view of a tape sticking apparatus in a first embodiment of the disclosure;

FIG. 2 is a plan view of the tape sticking apparatus in the first embodiment of the disclosure;

FIG. 3 is a perspective view of a tape sticking unit included in a tape sticking apparatus in the first embodiment of the disclosure;

FIG. 4 is a side view of the tape sticking unit included in the tape sticking apparatus in the first embodiment of the disclosure;

FIG. 5 is a perspective view of a backup stage included in the tape sticking apparatus in the first embodiment of the disclosure;

FIG. 6 is a block diagram illustrating a control system of the tape sticking apparatus in the first embodiment of the disclosure;

FIG. 7 is a perspective view of the tape sticking apparatus in the first embodiment of the disclosure;

FIG. 8 is a side view illustrating a state where a board is supported by the backup stage included in the tape sticking apparatus in the first embodiment of the disclosure;

FIG. 9A is a view explaining an operation of sticking a tape slice to a board by the tape sticking apparatus in the first embodiment of the disclosure;

FIG. 9B is a view explaining an operation of sticking the tape slice to the board by the tape sticking apparatus in the first embodiment of the disclosure;

FIG. 9C is a view explaining an operation of sticking the tape slice to the board by the tape sticking apparatus in the first embodiment of the disclosure;

FIG. 9D is a view explaining an operation of sticking the tape slice to the board by the tape sticking apparatus in the first embodiment of the disclosure;

FIG. 10 is a perspective view of a backup stage included in a tape sticking apparatus in a second embodiment of the disclosure;

FIG. 11 is a side view illustrating a state where a board is supported by the backup stage included in the tape sticking apparatus in the second embodiment of the disclosure;

FIG. 12A is a perspective view illustrating the backup stage included in the tape sticking apparatus in the second embodiment of the disclosure together with a board to which an existing board is attached;

FIG. 12B is a perspective view illustrating the backup stage included in the tape sticking apparatus in the second embodiment of the disclosure together with the board to which the existing board is attached; and

FIG. 13 is a perspective view of a backup stage included in a tape sticking apparatus in a third embodiment of the disclosure.

### DETAILED DESCRIPTION

Prior to describing an embodiment, problems in the related art will be briefly described.

In a tape sticking apparatus of the related art, a backup stage is simply supported by a lower surface of an end region of a board. Therefore, in a case where the board is not a glass board but is formed of a film-shaped member having a low rigidity such as a flexible board, there is a problem that the end region of the board is pulled and lifted up and the portion (end region of the board) may be deformed or the like when a separator is pulled up from a tape slice stuck to the board.

Therefore, an object of the disclosure is to provide a tape sticking apparatus which is capable of preventing a situation that an end region of a board is pulled and lifted up and the portion is deformed or the like when a separator is pulled and lifted up from a tape slice stuck to the board formed of a film-shaped member, and a tape sticking method.

Hereinafter, an embodiment will be described with reference to the drawings.

### First Embodiment

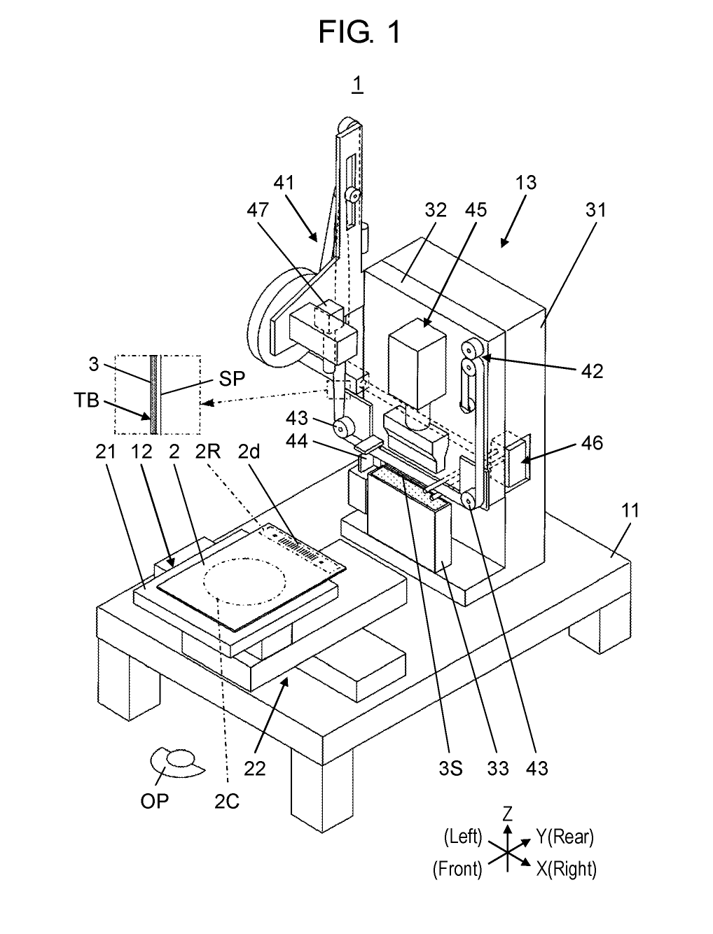

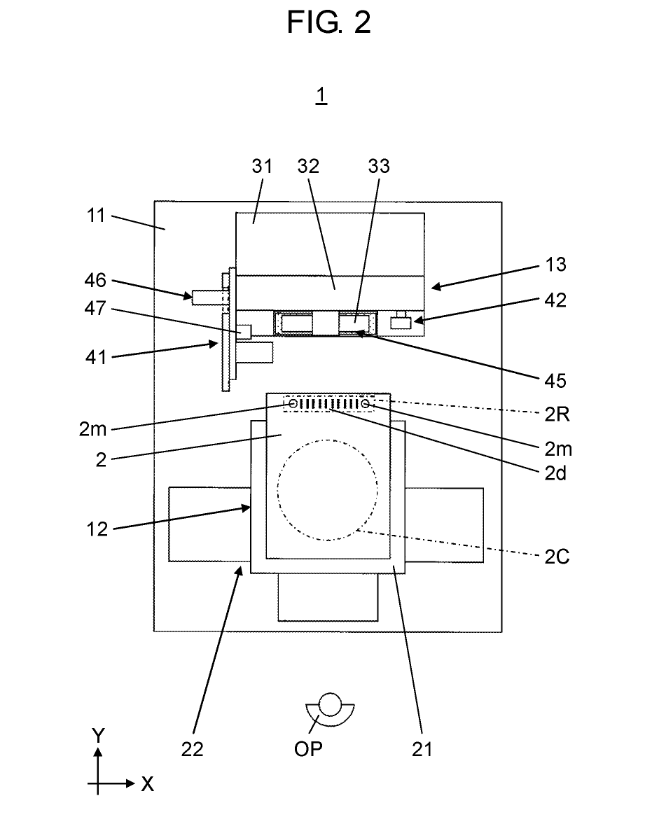

First, a first embodiment will be described. FIGS. 1 and 2 illustrate tape sticking apparatus 1 in the first embodiment. Tape sticking apparatus 1 is an apparatus for sticking tape slice 3S formed by cutting bonding tape 3 in a predetermined length to end region 2R of board 2.

In the following description, a rightward and leftward direction of tape sticking apparatus 1 viewed from operator OP is defined as an X-axis direction and a forward and rearward direction is defined as a Y-axis direction. An upward and downward direction is defined as a Z-axis direction. A surface positioned in a positive direction of a Z-axis (direction of an arrow of a Z-axis illustrated in the drawings) is defined as an upper surface and a surface positioned in a negative direction of the Z-axis is defined as a lower surface. The positive direction of the Z-axis is defined as upward and the negative direction of the Z-axis is defined as downward. In each member, a positive direction side of the Z-axis is defined as an upper portion and a negative direction side is defined as a lower portion.

In FIGS. 1 and 2, tape sticking apparatus 1 includes board moving unit 12 and tape sticking unit 13 on base 11. Board moving unit 12 is provided on a front side (operator OP side) of base 11. Tape sticking unit 13 is provided rearward of board moving unit 12.

In FIGS. 1 and 2, board 2 has a rectangular shape and is formed of a film-shaped member. Electrode 2d is provided on an upper surface of end region 2R of board 2. A pair of board-side marks 2m is provided at positions sandwiching both ends of electrode 2d in the X-axis direction.

In FIGS. 1 and 2, board moving unit 12 includes board holding table 21 holding board 2 and table moving mechanism 22 moving board holding table 21. Board holding table 21 holds a lower surface of center region 2C of board 2 in suction holes (not illustrated) provided on the upper surface thereof. Table moving mechanism 22 operates board holding table 21 and moves board 2 held by board holding table 21 in the X-axis direction, the Y-axis direction, and the Z-axis direction.

In FIG. 1, tape sticking unit 13 includes base portion 31, base plate 32, and backup stage 33 provided on base 11. Base plate 32 has a shape extending in an X-Z plane and backup stage 33 is positioned below base plate 32. Base plate 32 is provided with tape supply unit 41, tape feed unit 42, right and left tape guide rollers 43, cutter unit 44, pressing mechanism 45, peeling mechanism 46, and imaging camera 47.

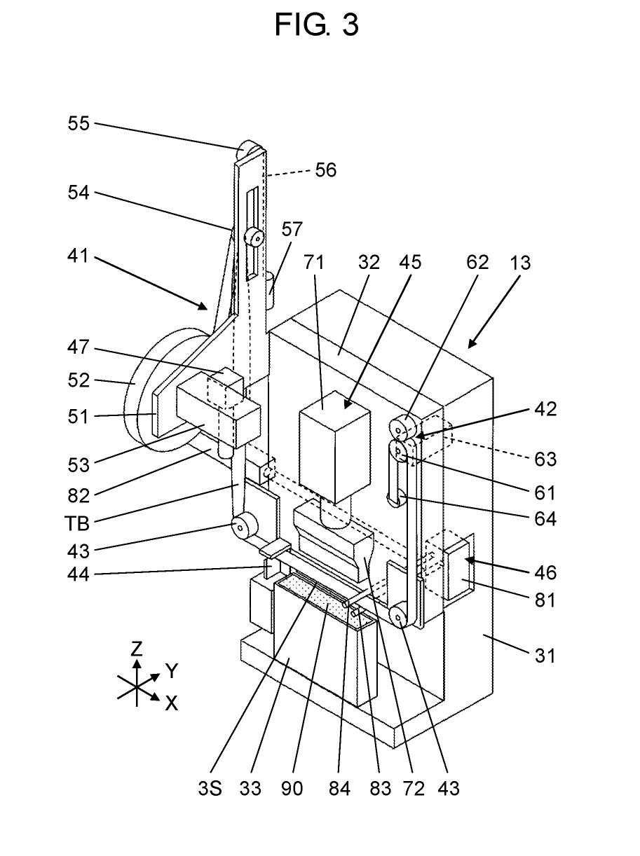

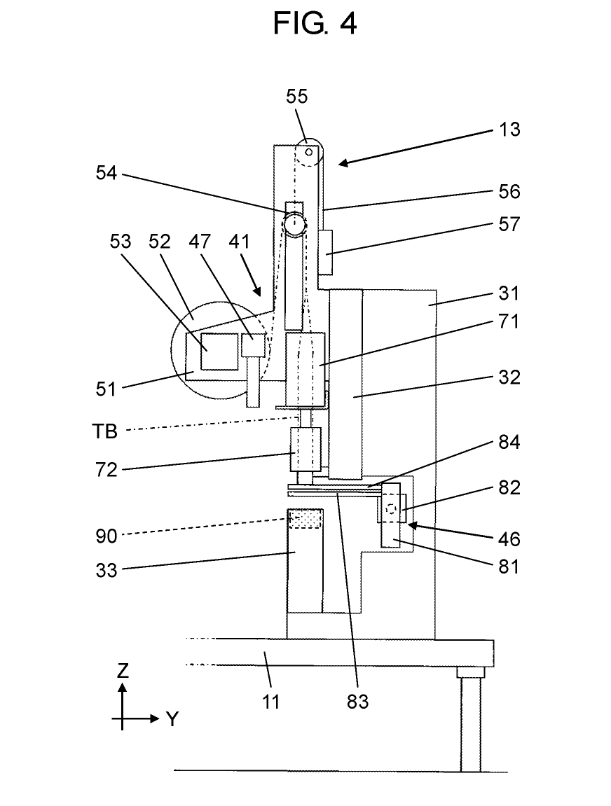

In FIGS. 3 and 4, tape supply unit 41 has bracket 51, reel 52, reel drive motor 53, elevation pulley 54, fixed pulley 55, wire member 56, and weight member 57. Bracket 51 is provided at an upper portion of a left side of base plate 32 to extend upward. Reel 52 is rotatably provided around the X-axis on a left surface side of bracket 51. Reel drive motor 53 is provided on a right surface side of bracket 51 and rotates reel 52 around the X-axis. Tape member TB (FIG. 1) formed by attaching separator SP to bonding tape 3 for bonding a component such as an anisotropic conductive film (ACF) is wound on reel 52.

In FIGS. 3 and 4, elevation pulley 54 is movably provided in bracket 51 in the upward and downward direction. Fixed pulley 55 is positioned above elevation pulley 54. Wire member 56 is stretched over fixed pulley 55 and one end of wire member 56 is connected to elevation pulley 54. Weight member 57 is connected to the other end of wire member 56.

In FIG. 3, tape feed unit 42 includes feed roller 61, pitch roller 62, feed roller drive motor 63, and tape recovery unit 64. Feed roller 61 is rotatably provided around the Y-axis at an upper portion on a right side of a front surface of base plate 32. Pitch roller 62 is provided above feed roller 61. Feed roller drive motor 63 rotates feed roller 61 around the Y-axis. Tape recovery unit 64 is provided to open to a front surface of base plate 32 below feed roller 61.

In FIG. 3, right and left tape guide rollers 43 are provided at right and left positions at the lowermost portion on the front surface of base plate 32. Tape member TB drawn out upward from reel 52 is stretched over elevation pulley 54 and then extends downward on the left side of base plate 32. Right and left tape guide rollers 43 guide tape member TB so that tape member TB extending downward on the left side of base plate 32 changes a direction thereof in a horizontal direction (from the left side to the right side) and extends above backup stage 33 in a horizontal posture with separator SP facing upward.

In FIGS. 1 and 3, tape member TB guided by right and left tape guide rollers 43 above backup stage 33 in the horizontal direction extend upward on the right side of base plate 32 and then is sandwiched by feed roller 61 and pitch roller 62 to be guided to tape recovery unit 64. However, as described below, bonding tape 3 of tape member TB is cut out as tape slice 3S, is stuck to board 2 at an intermediate portion of right and left tape guide rollers 43, and is separated from separator SP. Therefore, only separator SP is led to tape recovery unit 64. Elevation pulley 54 is pulled and lifted upward by weight member 57 via wire member 56 stretched over fixed pulley 55. Therefore, constant tension always acts on tape member TB pulled out from reel 52.

When feed roller drive motor 63 intermittently rotates feed roller 61 from a state where the tension acts on tape member TB, feed roller 61 winds tape member TB sandwiched between feed roller 61 and pitch roller 62 by a certain distance. Therefore, tape member TB advance a certain distance wound by feed roller 61 and elevation pulley 54 is pulled down by tape member TB. If elevation pulley 54 is pulled down, reel drive motor 53 rotates reel 52 and tape member TB to feed out tape member TB by a length wound by feed roller 61. Therefore, elevation pulley 54 returns to an original height position. Here, elevation pulley 54 functions as a buffer for securing the length of tape member TB, which is sent by feed roller 61, fed out from reel 52. Tape member TB (specifically, separator SP) wound around feed roller 61 is sucked by tape recovery unit 64 to be collected.

In FIGS. 1 and 3, cutter unit 44 is provided below the front surface of base plate 32 on the left side. Cutter unit 44 cuts bonding tape 3 without cutting separator SP in a process in which tape member TB extending below the left side of base plate 32 is guided by right and left tape guide rollers 43 above base plate 32 in the horizontal direction (from the left side to the right side). Therefore, tape slice 3S having a predetermined length corresponding to a length sent by feed roller 61 is formed on the lower surface of separator SP. Tape slice 3S formed on the lower surface of separator SP is guided to the right side from separator SP and is positioned above backup stage 33 in the horizontal posture with separator SP facing upward (therefore, a sticking surface to board 2 faces downward).

In FIGS. 3 and 4, pressing mechanism 45 includes pressing cylinder 71 and pressing tool 72. Pressing cylinder 71 is attached to the center portion of the front surface of base plate 32 in a posture in which piston rod 71R faces downward. Pressing tool 72 extends in the X-axis direction and is attached to a lower end of piston rod 71R of pressing cylinder 71.

In FIGS. 3 and 4, peeling mechanism 46 includes pin unit 81 and peeling cylinder 82. Pin unit 81 is disposed on a rear surface side of base plate 32 on the right side from pressing tool 72 and has two pin members (right pin 83 and left pin 84) extending to protrude horizontally forward. Right pin 83 and left pin 84 extend to protrude on the front surface of base plate 32 from below base plate 32. Peeling cylinder 82 is provided in a horizontal posture on the left side of base plate 32 on a rear surface side. Peeling cylinder 82 moves pin unit 81 in the X-axis direction.

In FIG. 3, right pin 83 is positioned on a lower surface side of separator SP and left pin 84 is positioned on an upper surface side of separator SP on the left side of right pin 83. That is, separator SP is in a state of being sandwiched by the two pin members (right pin 83 and left pin 84) on the right side of pressing tool 72.

In FIGS. 3 and 4, imaging camera 47 is provided in bracket 51. Imaging camera 47 is configured in a manner that an imaging field of view faces downward and images board-side marks 2m positioned within the imaging field of view on the front side of tape member TB extending between right and left tape guide rollers 43 in the horizontal direction.

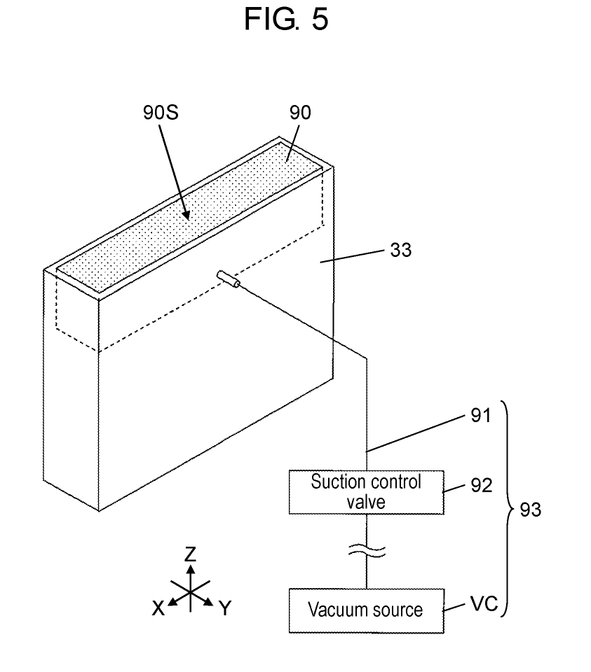

In FIG. 5, backup stage 33 has block-like porous material portion 90 made of a porous material on an upper portion thereof (also see FIG. 3). Upper surface 90S of porous material portion 90 is an upper surface of backup stage 33 and is a support surface supporting the lower surface of end region 2R of board 2 of which center region 2C is held by board holding table 21 (see FIG. 1).

In FIG. 5, suction pipe line 91 connected to porous material portion 90 is provided in backup stage 33. Suction pipe line 91 is connected to suction control valve 92 extends outside backup stage 33. Suction control valve 92 is connected to vacuum source VC provided outside tape sticking apparatus 1. When suction control valve 92 is operated and a vacuum pressure is supplied from vacuum source VC to suction pipe line 91, a suction force is generated on upper surface 90S of porous material portion 90 through pores of a porous material constituting porous material portion 90. If the suction force is generated on upper surface 90S of porous material portion 90 in a state where end region 2R of board 2 is supported by backup stage 33, end region 2R of board 2 is stuck to porous material portion 90 side and is in close contact with upper surface 90S of porous material portion 90.

As described above, in tape sticking apparatus 1 of the first embodiment, vacuum source VC and suction control valve 92 form suction mechanism 93 which sucks end region 2R of board 2 through the pores of porous material portion 90 provided at the upper end of backup stage 33 (FIG. 5).

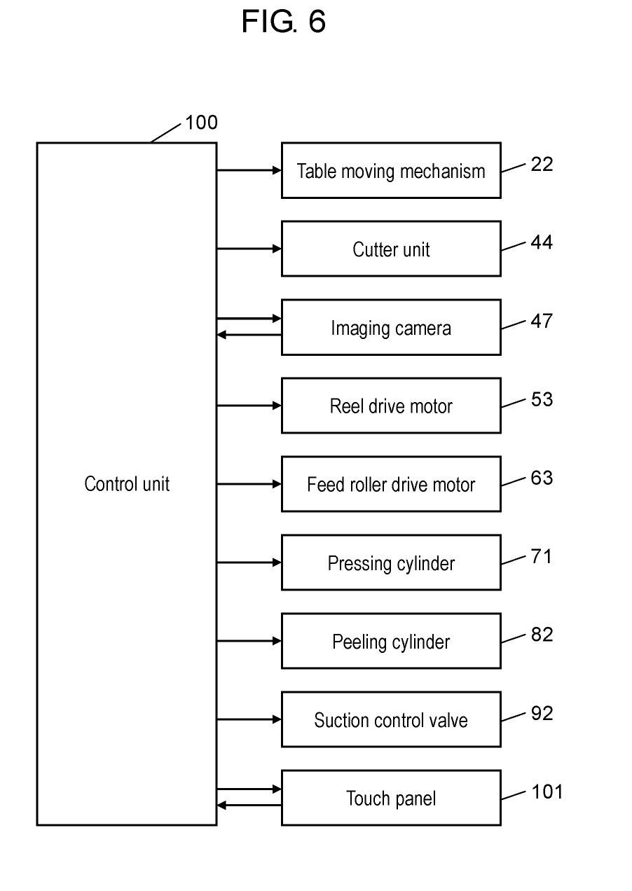

In FIG. 6, control unit 100 included in tape sticking apparatus 1 controls each operation of the movement of board holding table 21 by table moving mechanism 22, the cutting of bonding tape 3 by cutter unit 44, the imaging by imaging camera 47, the intermittent rotation of reel 52 by reel drive motor 53, and the intermittent rotation of feed roller 61 by feed roller drive motor 63. Control unit 100 controls each operation of the raising and lowering of pressing tool 72 by pressing cylinder 71, the movement of pin unit 81 by peeling cylinder 82, and the generation of the suction force to upper surface 90S of porous material portion 90 by suction control valve 92.

In FIG. 6, image data of board-side mark 2m obtained by imaging of imaging camera 47 is sent to control unit 100 and an image recognition process is performed. Control unit 100 is connected to touch panel 101 as an input and output device and operator OP can perform a desired input to tape sticking apparatus 1 through touch panel 101. Operator OP can obtain various kinds of information relating to tape sticking apparatus 1 through touch panel 101.

Next, an executing procedure of a tape sticking operation for sticking tape slice 3S to board 2 by tape sticking apparatus 1 (see FIG. 1) will be described. In the tape sticking operation, first, board holding table 21 receives board 2 sent from an upstream step and sticks and holds center region 2C thereof.

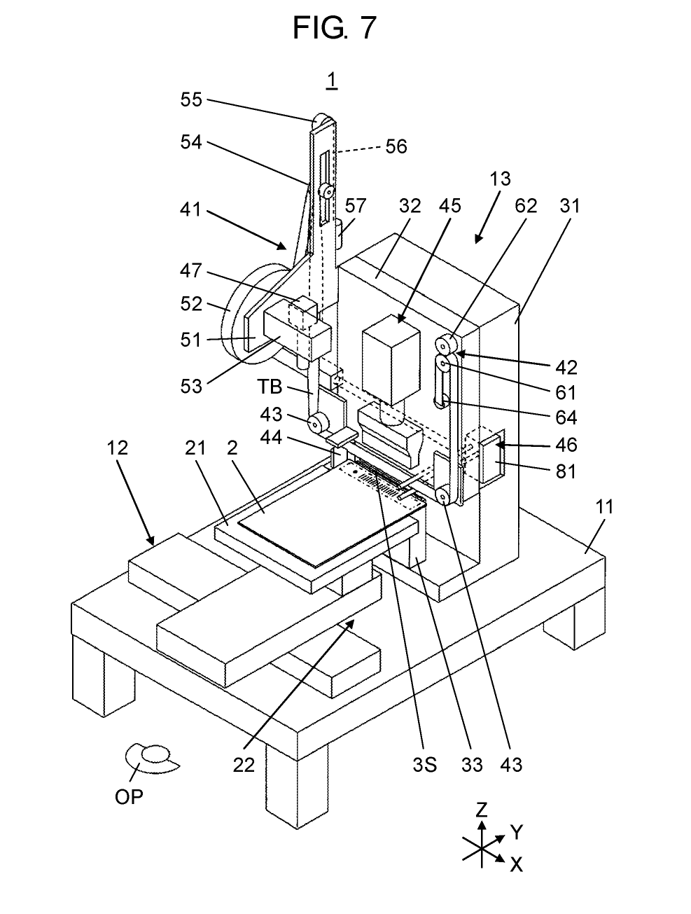

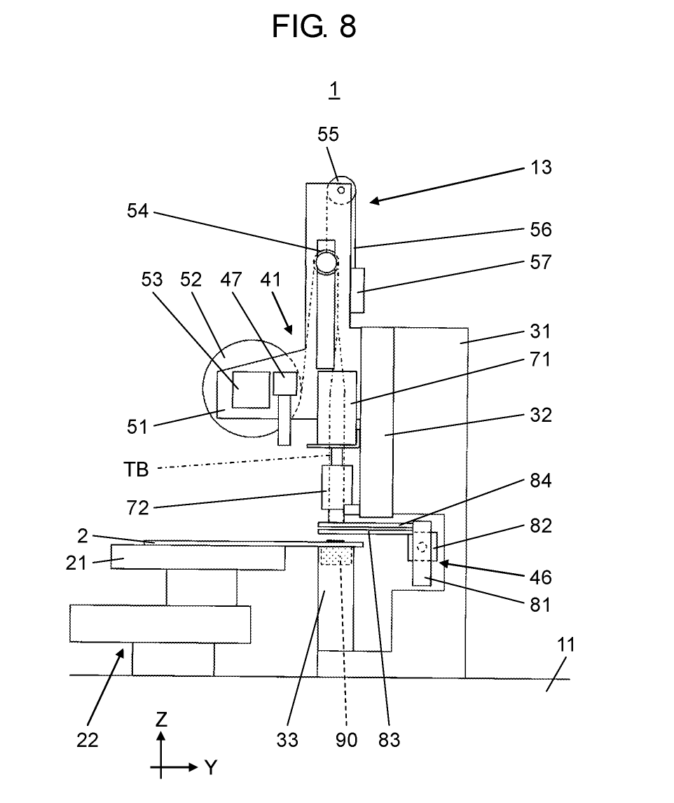

When board holding table 21 sucks and holds center region 2C of board 2, table moving mechanism 22 operates to move board holding table 21 and two board-side marks 2m included in board 2 are sequentially imaged by imaging camera 47. When imaging camera 47 images two board-side marks 2m (see FIG. 2), table moving mechanism 22 supports the lower surface of end region 2R of board 2 on the upper surface (upper surface 90S of porous material portion 90, see FIG. 5) of backup stage 33 (FIGS. 7 and 8) (board end region support step).

When the lower surface of end region 2R of board 2 is supported by backup stage 33, control unit 100 operates suction control valve 92 and the suction force is generated on upper surface 90S of porous material portion 90. Therefore, end region 2R of board 2 is sucked on the upper surface side of porous material portion 90 and is in close contact with upper surface 90S of porous material portion 90 (board end region sucking step).

Here, end region 2R of board 2 is sucked on an inside side of the pores of porous material portion 90 in a state of being in close contact with the upper surface of porous material portion 90. A hole diameter of the pores of porous material portion 90 is substantially 60 μm and is sufficiently smaller than a thickness of board 2. Therefore, the surface of board 2 is not pulled into the inside of the pores or voids do not occur in board 2.

When end region 2R of board 2 is sucked through porous material portion 90, control unit 100 the intermittently rotates tape feed roller 61 by feed roller drive motor 63 (see FIG. 3) and intermittently rotates reel 52 by reel drive motor 53, thereby advancing tape member TB by a fixed distance. At the same time, control unit 100 causes tape recovery unit 64 to perform the suction operation and collect used tape member TB (separator SP).

As described above, control unit 100 causes cutter unit 44 to cut bonding tape 3 in synchronization with the intermittent rotation of tape feed roller 61 while advancing tape member TB by a fixed distance so that tape slice 3S having a predetermined length is formed on the lower surface of separator SP. Tape member TB is intermittently sent by a fixed distance and thereby tape slice 3S formed on the lower surface of separator SP passes through below (above backup stage 33) pressing tool 72 in the horizontal posture with separator SP facing upward.

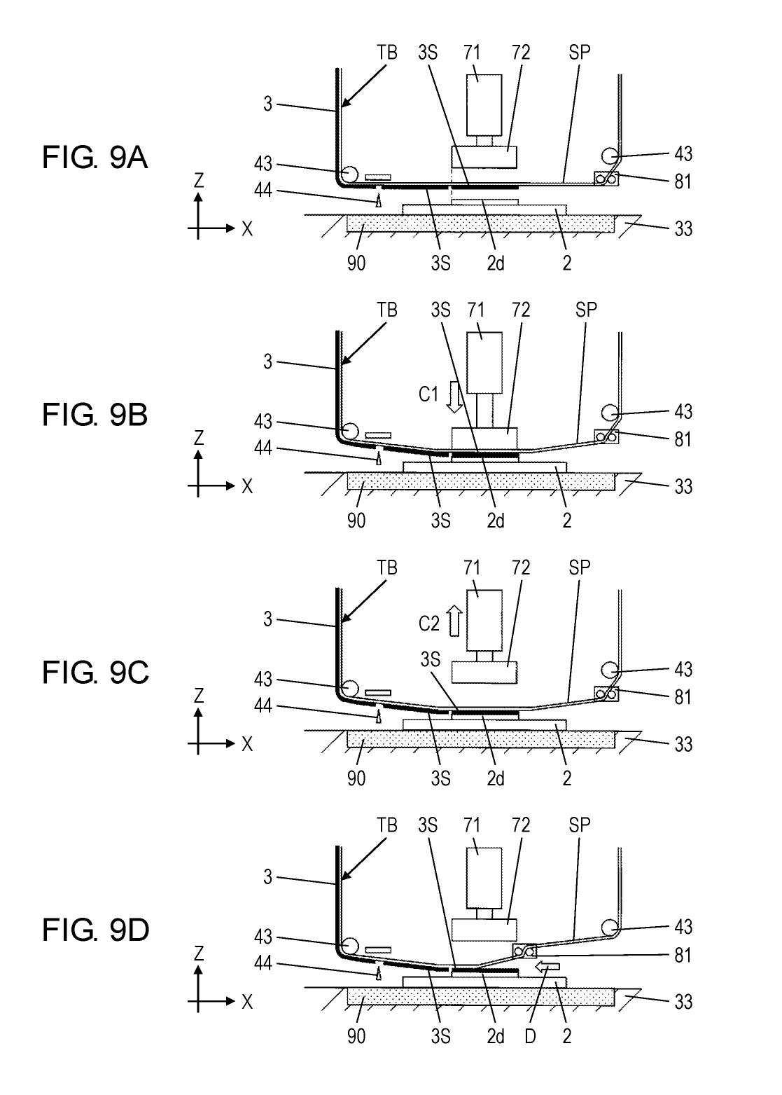

Tape member TB is guided by right and left tape guide rollers 43, a column among a plurality of columns of tape slices 3S formed on the lower surface of separator SP is positioned at a head portion in an advancing direction is positioned at a lower position of pressing tool 72 (FIG. 9A), control unit 100 operates pressing cylinder 71 to lower pressing tool 72 (arrow C1 illustrated in FIG. 9B) and pushes down tape slice 3S together with separator SP by pressing tool 72. Therefore, tape slice 3S is pressed against electrode 2d of board 2 of which the lower surface is supported by backup stage 33 (FIG. 9B) and bonding tape 3 is stuck to electrode 2d of board 2.

When bonding tape 3 is stuck to electrode 2d of board 2, control unit 100 operates pressing cylinder 71 to raise pressing tool 72 (FIG. 9C, arrow C2 illustrated in the drawing). When pressing tool 72 is raised, control unit 100 operates peeling cylinder 82 (see FIG. 8) and moves pin unit 81 from the right side to the left side (arrow D illustrated in FIG. 9D) of pressing tool 72. Therefore, the two pin members (right pin 83 and left pin 84) constituting pin unit 81 pass through below pressing tool 72 from the right side to the left side and separator SP sandwiched by the two pin members is pulled up from the upper surface of tape slice 3S stuck to board 2 to be separated from tape slice 3S.

As described above, when separator SP is pulled up, tape slice 3S is pulled and lifted upward by an adhesive force between separator SP and tape slice 3S. However, since board 2 is sucked on upper surface 90S side of porous material portion 90 through porous material portion 90, end region 2R of board 2 is not pulled and lifted upward.

When separator SP is separated from tape slice 3S, peeling cylinder 82 moves pin unit 81 on the right side to return to the original position. When pin unit 81 returns to the original position, suction control valve 92 operates to release the suction of end region 2R of board 2, and table moving mechanism 22 moves board holding table 21 on the front side to position board 2 at a delivery position (position on the front right side of base 11) to a downstream step side. Therefore, tape sticking work is completed.

As described above, in tape sticking apparatus 1 in the embodiment, end region 2R of board 2 is supported by porous material portion 90 provided at the upper portion of backup stage 33 and end region 2R of board 2 is sucked through the pores included in porous material portion 90. Therefore, even in a case where board 2 is formed of the film-shaped member, it is possible to prevent a situation that end region 2R of board 2 is pulled and lifted up and the portion (end region 2R) is deformed or the like when the separator SP is pulled up from the stuck tape slice 3S.

### Second Embodiment

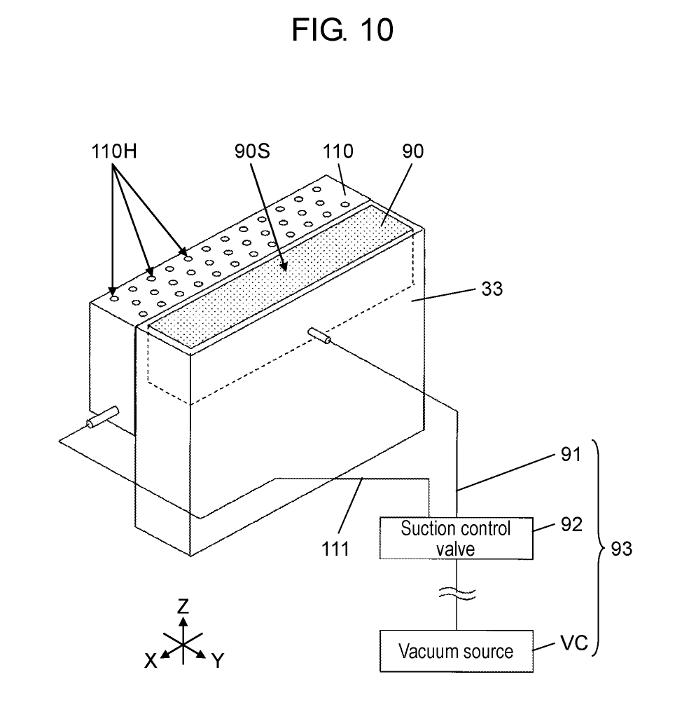

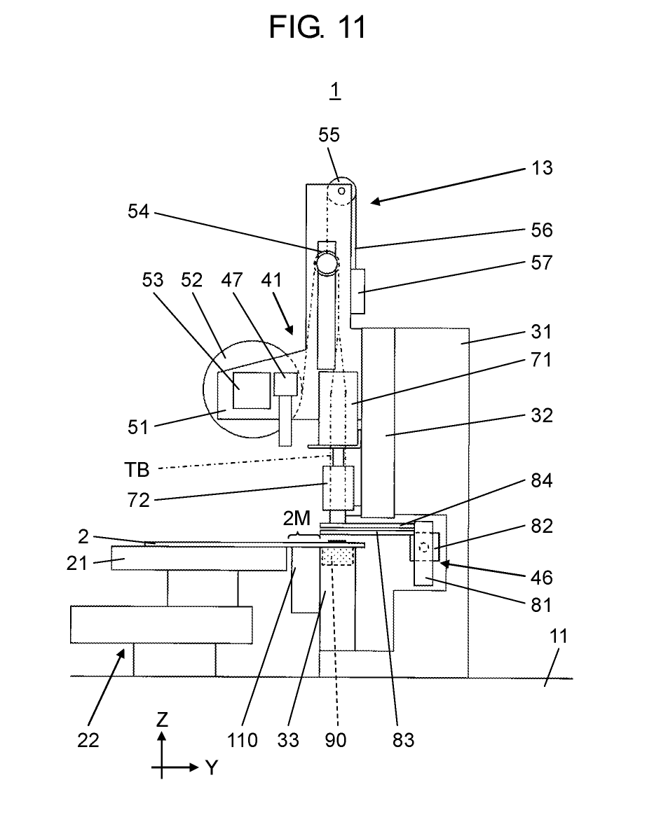

Next, a second embodiment will be described. As illustrated in FIGS. 10 and 11, tape sticking apparatus 1 in the second embodiment is configured to provide block-like auxiliary support member 110 on a front surface of backup stage 33 included in tape sticking apparatus 1 in the first embodiment. An upper surface of auxiliary support member 110 has the same height as that of upper surface 90S of porous material portion 90 and supports a lower surface side of intermediate portion 2M (FIG. 11) positioned on a center region 2C side of board 2 rather than end region 2R of board 2.

In FIG. 10, a plurality of suction ports 110H opened on an upper surface are formed in auxiliary support member 110. Auxiliary support member 110 is provided with auxiliary suction pipe line 111 connected to each suction port 110H. Auxiliary suction pipe line 111 extends to the outside of auxiliary support member 110 and is connected to suction control valve 92 described above.

An end region (same as end region 2R of the first embodiment illustrated in FIG. 1) of board 2 of which a center region (same as center region 2C of the first embodiment illustrated in FIG. 1) is held by board holding table 21 is supported by upper surface 90S (that is, an upper surface of backup stage 33) of porous material portion 90 (board end region supporting step). Intermediate portion 2M of board 2 is supported by the upper surface of auxiliary support member 110 (FIG. 11) (board intermediate portion supporting step). End region 2R of board 2 is supported by upper surface 90S of porous material portion 90. In a case where intermediate portion 2M of board 2 is supported by the upper surface of auxiliary support member 110, suction control valve 92 operates. When a vacuum pressure from vacuum source VC is supplied to suction pipe line 91 and auxiliary suction pipe line 111, porous material portion 90 sucks end region 2R of board 2 through the pores (board end region sucking step). The plurality of suction ports 110H opened on the upper surface of auxiliary support member 110 sucks intermediate portion 2M of the board (board intermediate portion sucking step).

Therefore, similar to the case of the first embodiment, even in a case where board 2 is formed of the film-shaped member, it is possible to prevent a situation that end region 2R of board 2 is pulled and lifted up and the portion (end region 2R) is deformed or the like when the separator SP is pulled up from the stuck tape slice 3S.

Here, a hole diameter of each of the plurality of suction ports 110H formed in auxiliary support member 110 is such that suck intermediate portion 2M of board 2 is not pulled into the inside of suction port 110H or voids do not occur in board 2. Specifically, the hole diameter of suction port 110H is substantially 0.3 mm or less.

In tape sticking apparatus 1 in the second embodiment, it is preferable that auxiliary support member 110 is detachably attached to backup stage 33. Therefore, it is possible to prepare a plurality of auxiliary support members 110 having different dimensions in the Y-axis direction and to support board 2 in an optimum state by attaching auxiliary support member 110 having an appropriate upper region according to a size (dimension in the Y-axis direction) of intermediate portion 2M of board 2 to backup stage 33.

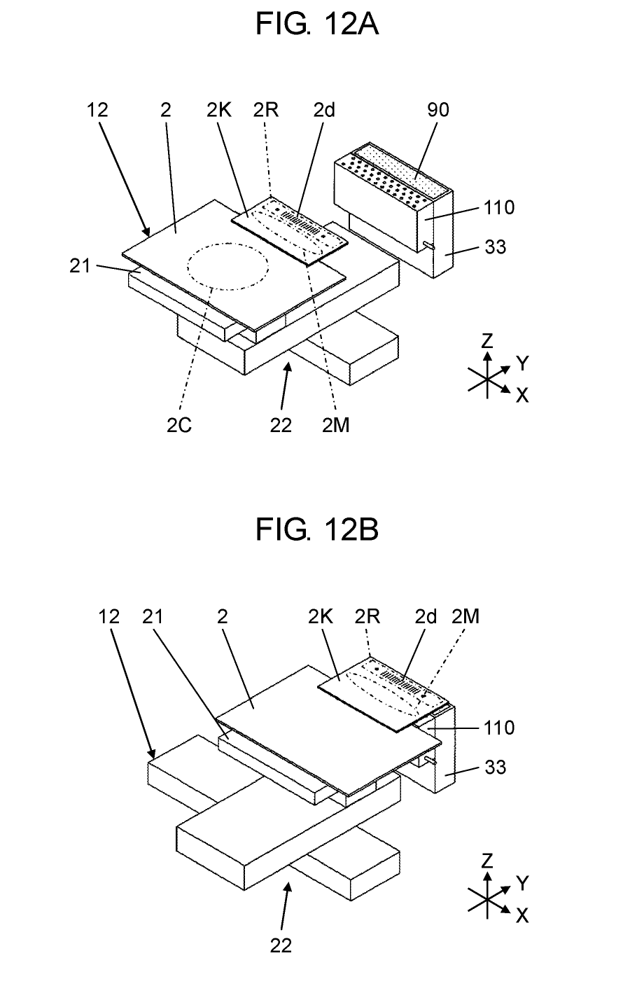

FIG. 12A is a view illustrating an example in which board 2 has extended portion 2K (for example, another board formed of a film-shaped member attached to end region 2R) and tape slice 3S is stuck so that a film-shaped component or the like is further attached to end region 2R of extended portion 2K. If center region 2C of board 2 is held by board holding table 21 and intermediate portion 2M of extended portion 2K of board 2 is held by auxiliary support member 110 (FIG. 12B), it is possible to stick tape slice 3S to end region 2R of board 2 (here, of extended portion 2K) in an extremely stable state.

### Third Embodiment

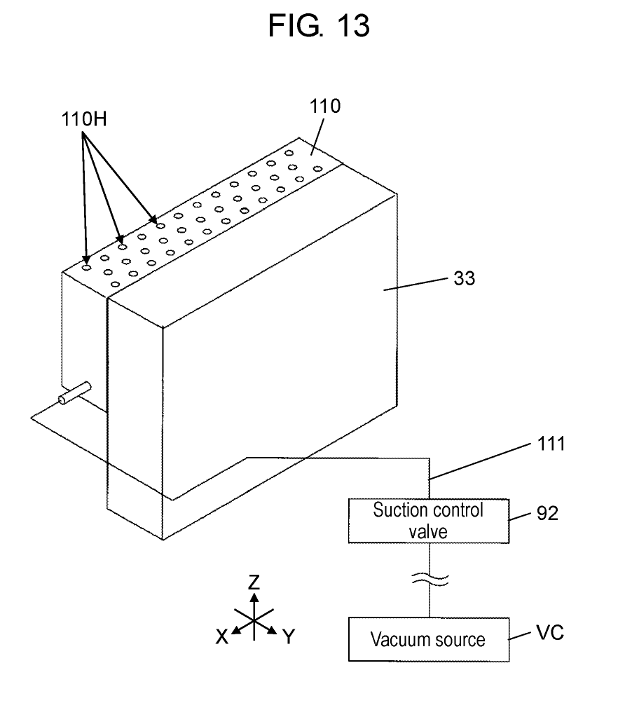

Next, a third embodiment will be described. Tape sticking apparatus 1 in the third embodiment has a configuration in which porous material portion 90 and suction pipe line 91 are removed from tape sticking apparatus 1 in the second embodiment (FIG. 13). In tape sticking apparatus 1 in the third embodiment, end region 2R of board 2 is supported by a horizontal upper surface of backup stage 33 and intermediate portion 2M of board 2 is supported and sucked by an upper surface of auxiliary support member 110.

In tape sticking apparatus 1 in the third embodiment, end region 2R of board 2 is placed on an upper surface of backup stage 33. If a dimension of the upper surface of backup stage 33 in the Y-axis is small and suction ports 110H provided in auxiliary support member 110 are provided at positions close to end region 2R of board 2, even in a case where board 2 is formed of the film-shaped member, it is possible to prevent a situation that end region 2R of board 2 is pulled and lifted up and the portion (end region 2R) is deformed or the like when the separator SP is pulled up from the stuck tape slice 3S.

### Conclusion

As described above, tape sticking apparatus 1 of the embodiment is a tape sticking apparatus in which end region 2R of board 2 formed of the film-shaped member is supported by backup stage 33, tape slice 3S for bonding a component is pressed against end region 2R of board 2 together with separator SP attached to the upper surface of tape slice 3S to stick tape slice 3S to end region 2R of board 2, and then separator SP is pulled up from tape slice 3S to separate separator SP from tape slice 3S. Tape sticking apparatus 1 in the embodiment, includes porous material portion 90 which is provided at the upper portion of backup stage 33 and supports the lower surface of end region 2R of board 2, and suction mechanism 93 which sucks end region 2R of board 2 through porous material portion 90.

The tape sticking method in the embodiment, is a tape sticking method in which end region 2R of board 2 formed of the film-shaped member is supported by backup stage 33, tape slice 3S for bonding a component is pressed against end region 2R of board 2 together with separator SP attached to the upper surface of tape slice 3S to stick tape slice 3S to end region 2R of board 2, and then separator 3S is pulled up from tape slice 3S to separate separator SP from tape slice 3S. The tape sticking method in the embodiment includes the board end region supporting step of supporting the lower surface of end region 2R of the board by porous material portion 90 provided at the upper portion of backup stage 33, and the board end region sucking step of sucking end region 2R of board 2 through porous material portion 90 by suction mechanism 93.

The disclosure provides the tape sticking apparatus which can prevent a situation in which the end region of the board is pulled and lifted up and the portion is deformed or the like when pulling up the separator from the tape slice stuck to the board formed of the film-shaped member, and the tape sticking method.

What is claimed is:

1. A tape sticking apparatus which supports an end region of a board formed of a film-shaped member by a backup stage, presses a tape slice for bonding a component against the end region of the board together with a separator attached to an upper surface of the tape slice to stick the tape slice to the end region of the board, and then pulls up the separator from the tape slice to separate the separator from the tape slice, the apparatus comprising:
a porous material portion which is provided at an upper portion of the backup stage and supports a lower surface of the end region of the board; and
a suction mechanism which sucks the end region of the board through the porous material portion.

2. The tape sticking apparatus of claim 1, further comprising:
an auxiliary support member which is provided in the backup stage, of which an upper surface has the same height as a height of an upper surface of the porous material portion, and which supports a lower surface of an intermediate portion positioned at a center region side of the board with respect to the end region of the board,
wherein the suction mechanism sucks the intermediate portion of the board through a plurality of suction ports provided to open to the upper surface of the auxiliary support member.

3. The tape sticking apparatus of claim 2,
wherein a hole diameter of each of the plurality of suction ports is sized such that voids are not generated in the board to be sucked.

4. The tape sticking apparatus of claim 2,
wherein the auxiliary support member is detachably attached to the backup stage.

5. A tape sticking method in which an end region of a board formed of a film-shaped member is supported by a backup stage, a tape slice for bonding a component is pressed against the end region of the board together with a separator attached to an upper surface of the tape slice to stick the tape slice to the end region of the board, and then the separator is pulled up from the tape slice to separate the separator from the tape slice, the method comprising:
a board end region supporting step of supporting a lower surface of the end region of the board by a porous material portion provided at an upper portion of the backup stage; and
a board end region sucking step of sucking the end region of the board through the porous material portion by a suction mechanism.
